(19) United States
(12) Patent Application Publication
(10) Pub. No.: US 2023/0083747 A1
(43) Pub. Date: Mar. 16, 2023

(54) SEMICONDUCTOR DEVICES

(71) Applicant: Samsung Electronics Co., Ltd., Suwon-si (KR)

(72) Inventors: Ja Yeong Heo, Hwaseong-si (KR); Yeong Gil Kim, Hwaseong-si (KR); Woo Jin Lee, Hwaseong-si (KR)

(21) Appl. No.: 17/931,873

(22) Filed: Sep. 13, 2022

(30) Foreign Application Priority Data
Sep. 16, 2021 (KR) 10-2021-0123574

(51) Int. Cl. H01L 23/532; H01L 23/522; H01L 23/528

(52) U.S. Cl. CPC H01L 23/53295; H01L 23/5226; H01L 23/5283; H01L 23/53238

(57) ABSTRACT

A semiconductor device is provided. A semiconductor device includes: a lower metal layer including first, second, and third conductive patterns spaced apart from each other in a first insulating film; first and second interlayer insulating films between the first and second conductive patterns and between the second and third conductive patterns, respectively, so as to be spaced apart from each other; a via metal layer inside a recess on the lower metal layer and electrically connected to the lower metal layer; and a second insulating film at least partially surrounding side surfaces of the via metal layer and having a first insulating film portion on a concave portion between the first and second interlayer insulating films and a second insulating film portion on the first insulating film portion, wherein a carbon concentration in the first insulating film portion is higher than a carbon concentration in the second insulating film portion.

### CROSS-REFERENCE TO RELATED APPLICATION

This application claims priority from Korean Patent Application No. 10-2021-0123574 filed on Sep. 16, 2021, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device.

### 2. Description of the Related Art

As down-scaling of semiconductor elements has rapidly progressed in recent years due to the development of an electronic technology, high integration and low power consumption of semiconductor chips have been demanded.

In order to respond to the demand for the high integration and the low power consumption of the semiconductor elements, a feature size of the semiconductor elements has continuously decreased, and a dielectric constant (k) of an intermetallic insulating film in a back end-of-line (BEOL) process has continuously decreased.

Meanwhile, as the feature size decreases, it may become an important challenge to improve resistive capacitance and reliability of a dielectric film disposed between wirings.

### SUMMARY

Aspects of the present disclosure provide a semiconductor device in which reliability of an electrical connection between a via metal layer and a lower metal layer is improved.

Aspects of the present disclosure also provide a semiconductor device in which a pore of an uneven structure caused by selectively forming an interlayer insulating film on a low-k insulating material is reduced or eliminated.

Aspects of the present disclosure also provide a semiconductor device in which a wiggling phenomenon (undulation) of a via metal layer caused by patterning the via metal layer on a low-k insulating material is prevented.

According to an embodiment of the present disclosure, there is a semiconductor device comprising a lower metal layer comprising: first, second, and third conductive patterns spaced apart from each other in a first insulating film; a first interlayer insulating film between the first and second conductive pattern; a second interlayer insulating film between the second and third conductive patterns, wherein the first interlayer insulating film and the second interlayer insulating film are spaced apart from each other on the first insulating film a via metal layer inside a recess on the lower metal layer, the via metal layer electrically connected to the lower metal layer and a second insulating film at least partially surrounding side surfaces of the via metal layer, the second insulating film comprising: a first insulating film portion on a concave portion between the first and second interlayer insulating films; and a second insulating film portion on the first insulating film portion, wherein a carbon concentration in the first insulating film portion is higher than a carbon concentration in the second insulating film portion.

According to the aforementioned and other embodiments of the present disclosure, there is provided a semiconductor device comprising: a lower metal layer in a first insulating film; an interlayer insulating film selectively formed on the first insulating film in one or more regions where the lower metal layer is not formed; a via metal layer on the lower metal layer and electrically connected to the lower metal layer; and a second insulating film at least partially surrounding side surfaces of the via metal layer and comprising: a first insulating film portion formed on the interlayer insulating film so as to have a first carbon concentration and a second insulating film portion formed on the first insulating film portion so as to have a second carbon concentration lower than the first carbon concentration.

According to the aforementioned and other embodiments of the present disclosure, there is provided a semiconductor device comprising: a lower metal layer comprising first, second, and third conductive patterns spaced apart from each other in a first insulating film; a first interlayer insulating film between the first and second conductive patterns; a second interlayer insulating film between the second and third conductive patterns, wherein the first interlayer insulating film and the second interlayer insulating film are spaced apart from each other on the first insulating film; a via metal layer inside a recess on the lower metal layer, the via metal layer electrically connected to the lower metal layer; and a second insulating film at least partially surrounding side surfaces of the via metal layer, the second insulating film comprising: a first insulating film portion on a concave portion between the first and second interlayer insulating films; and a second insulating film portion on the first insulating film portion, wherein the recess includes a first recess portion formed along the concave portion between the first and second interlayer insulating films, a second recess portion penetrating through the first insulating film portion and extending to the first recess, and a third recess portion penetrating through the second portion and extending to the second recess, and wherein a carbon concentration in the first insulating film portion is higher than a carbon concentration in the second insulating film portion.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram for describing an example semiconductor device according to some example embodiments of the present disclosure;

FIG. 2 is a cross-sectional view taken along line A-A of FIG. 1;

FIG. 3 is an enlarged view of part C of FIG. 2;

FIG. 4 is a cross-sectional view taken along line B-B of FIG. 1;

FIGS. 5 to 9 are views for describing an example method of manufacturing a semiconductor device according to some example embodiments of the present disclosure;

FIG. 10 is a view for describing an example semiconductor device according to some example embodiments of the present disclosure, and is a view corresponding to the cross-sectional view taken along line A-A of FIG. 1;

FIG. 11 is a view for describing an example semiconductor device according to some example embodiments of the present disclosure, and is a view corresponding to the cross-sectional view taken along line A-A of FIG. 1;

FIG. 12 is a view for describing an example semiconductor device according to some example embodiments of the present disclosure, and is a view corresponding to the cross-sectional view taken along line A-A of FIG. 1;

FIG. 13 is a view for describing an example semiconductor device according to some example embodiments of the present disclosure, and is a view corresponding to the cross-sectional view taken along line A-A of FIG. 1;

FIG. 14 is a view for describing an example semiconductor device according to some example embodiments of the present disclosure, and is a view corresponding to the cross-sectional view taken along line A-A of FIG. 1;

FIG. 15 is a view for describing an example semiconductor device according to some example embodiments of the present disclosure, and is a view corresponding to the cross-sectional view taken along line A-A of FIG. 1;

FIG. 16 is a view for describing an example semiconductor device according to some example embodiments of the present disclosure, and is a view corresponding to the cross-sectional view taken along line A-A of FIG. 1;

FIG. 17 is a view for describing an example semiconductor device according to some example embodiments of the present disclosure, and is a view corresponding to the cross-sectional view taken along line A-A of FIG. 1;

FIG. 18 is a view for describing an example semiconductor device according to some example embodiments of the present disclosure, and is a view corresponding to the cross-sectional view taken along line A-A of FIG. 1;

FIG. 19 is a view for describing an example semiconductor device according to some example embodiments of the present disclosure, and is a view corresponding to the cross-sectional view taken along line A-A of FIG. 1.

### DETAILED DESCRIPTION OF THE EMBODIMENTS

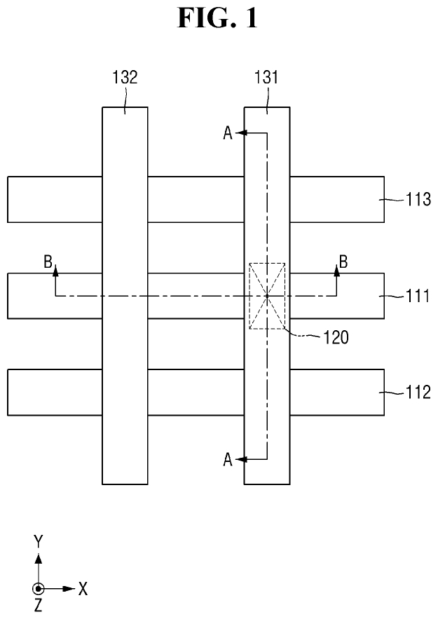

Hereinafter, an example semiconductor device according to some example embodiments of the present disclosure will be described with reference to FIGS. 1 to 4.

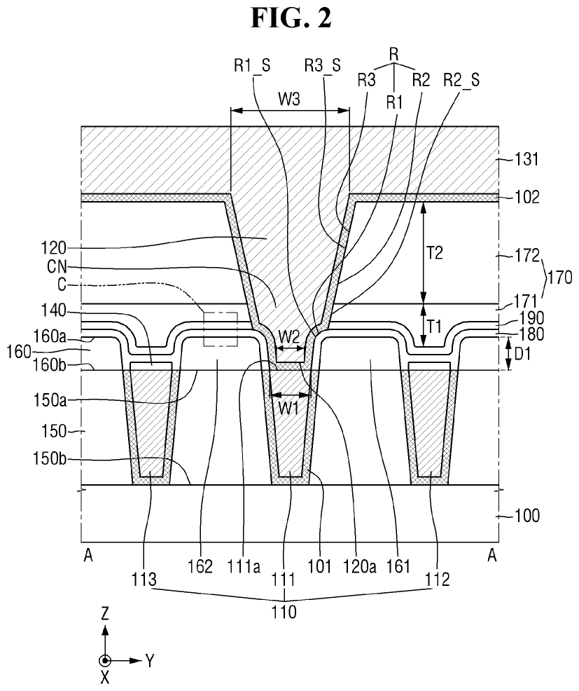

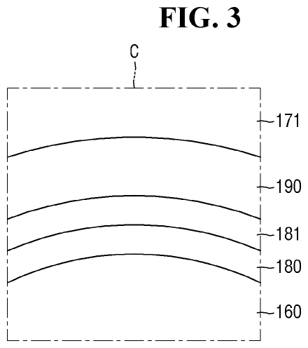

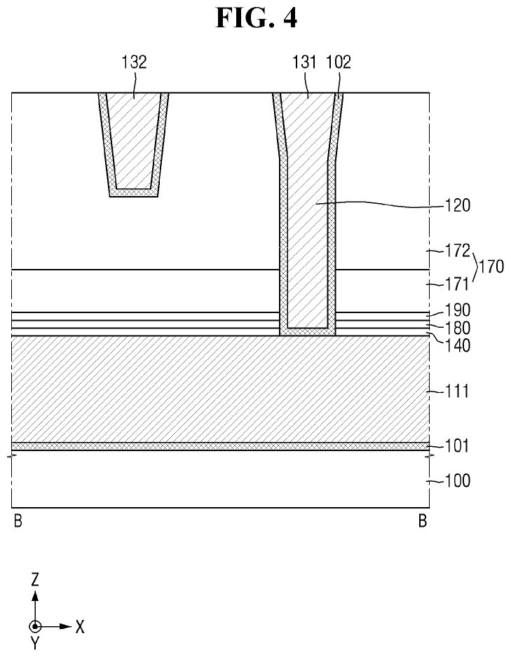

FIG. 1 is a layout diagram for describing an example semiconductor device according to some example embodiments of the present disclosure. FIG. 2 is a cross-sectional view taken along line A-A of FIG. 1. FIG. 3 is an enlarged view of part C of FIG. 2. FIG. 4 is a cross-sectional view taken along line B-B of FIG. 1.

Referring to FIGS. 1 to 4, an example semiconductor device according to some example embodiments of the present disclosure includes a lower metal layer 110 including a first lower conductive pattern 111, a second lower conductive pattern 112, and a third lower conductive pattern 113; an interlayer insulating film 160 including a first interlayer insulating film 161 and a second interlayer insulating film 162; a via metal layer 120; a second insulating film 170; a barrier dielectric film 180; and an etch stop film 190.

A lower insulating film 100 may have a structure in which a base substrate and an epitaxial layer are stacked, but the technical spirit of the present disclosure is not limited thereto. In some other example embodiments, the lower insulating film 100 may also be a silicon substrate, a gallium arsenide substrate, a silicon germanium substrate, a ceramic substrate, a quartz substrate, a display glass substrate, or the like, or be a semiconductor on insulator (SOI) substrate.

For example, when the lower insulating film 100 includes a silicon substrate, the lower insulating film 100 may include an insulating film formed on the silicon substrate.

In addition, although not illustrated, the lower insulating film 100 may include a conductive pattern. The conductive pattern may be a metal wiring, a contact, or the like, or be a gate electrode of a transistor, a source/drain of a transistor, a diode, or the like, but the technical spirit of the present disclosure is not limited thereto.

The lower insulating film 100 may be formed in a front end-of-line (FEOL) process. However, the technical spirit of the present disclosure is not limited thereto.

A first insulating film 150 may be disposed on the lower insulating film 100. The first insulating film 150 may include, for example, at least one of silicon oxide, silicon nitride, silicon oxynitride, and a low-k material.

For example, the first insulating film 150 may include a low-k material in order to reduce a coupling phenomenon between wirings. The low-k material may be, for example, silicon oxide with moderately high carbon and hydrogen, and may be a material such as SiCOH.

Meanwhile, carbon is included in an insulating material, and thus, a dielectric constant of the insulating material may be lowered. However, in order to further lower the dielectric constant of the insulating material, the insulating material may include a pore such as a cavity filled with gas or filled with air therein.

The low-k material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or combinations thereof, but the technical spirit of the present disclosure is not limited thereto.

In the semiconductor device according to some example embodiments of the present disclosure, the first insulating film 150 may include a low-k insulating material having a lower dielectric constant than silicon oxide.

Each of the first to third lower conductive patterns 111, 112, and 113 may be on the lower insulating film 100. Each of the first to third lower conductive patterns 111, 112, and 113 may be in the first insulating film 150 so as to penetrate through the first insulating film 150.

The first insulating film 150 may be between the first lower conductive pattern 111 and the second lower conductive pattern 112 and between the first lower conductive pattern 111 and the third lower conductive pattern 113. Specifically, the first insulating film 150 may be on a first side of the second lower conductive pattern 112 facing the first lower conductive pattern 111 and a first side of the third lower conductive pattern 113 facing the first lower conductive pattern 111.

Each of the first to third lower conductive patterns 111, 112, and 113 may extend in a first direction X. The second lower conductive pattern 112, the first lower conductive pattern 111, and the third lower conductive pattern 113 may be spaced apart from each other in a second direction Y that is perpendicular to the first direction X, and in some embodiments, may be sequentially spaced apart from each other.

For example, a width W1 of an upper surface 111a of the first lower conductive pattern 111 in the second direction Y may be fifteen nanometers (15) nm or less. However, the technical spirit of the present disclosure is not limited thereto.

However, an arrangement of each of the first to third lower conductive patterns 111, 112, and 113 is for convenience of explanation, and in some other example embodiments, an arrangement of each of the first to third lower conductive patterns 111, 112, and 113 may be changed.

Each of the first to third lower conductive patterns 111, 112, and 113 may include, for example, copper (Cu). However, the technical spirit of the present disclosure is not limited thereto.

When each of the first to third lower conductive patterns 111, 112, and 113 includes copper, the copper included in each of the first to third lower conductive patterns 111, 112, and 113 may also include, for example, at least one of carbon (C), silver (Ag), tungsten (W), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), molybdenum (Mo), ruthenium (Ru), and zirconium (Zr).

It has been illustrated in FIG. 2 that an upper surface of each of the first to third lower conductive patterns 111, 112, and 113 is flat, but this is only for convenience of explanation, and the technical spirit of the present disclosure is not limited thereto. That is, in some other example embodiments, the upper surface of each of the first to third lower conductive patterns 111, 112, and 113 may be convex upward or be convex downward.

A lower barrier film 101 may be between each of the first to third lower conductive patterns 111, 112, and 113 and the first insulating film 150. The lower barrier film 101 may be in contact with a lower surface 150b of the first insulating film 150.

Specifically, the lower barrier film 101 may be along a bottom surface and a sidewall of the first lower conductive pattern 111. The lower barrier film 101 may be along a bottom surface and a sidewall of the second lower conductive pattern 112. The lower barrier film 101 may be along a bottom surface and at least a portion of a sidewall of the third lower conductive pattern 113.

The lower barrier film 101 may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh).

The upper surface 111a of each of the first to third lower conductive patterns 111, 112, and 113 may be formed to have the same height as an upper surface 150a of the first insulating film 150.

The interlayer insulating film 160 may be on the first insulating film 150. The interlayer insulating film 160 may surround at least portions of side surfaces of a via metal layer 120 electrically connected to the lower metal layer 110, as will be described below. It will be understood that “an element A surrounds an element B” (or similar language) as used herein means that the element A is at least partially around the element B but does not necessarily mean that the element A completely encloses the element B.

The interlayer insulating film 160 may be on the first insulating film 150 and disposed in a region other than a region where the lower metal layer 110 is disposed. The interlayer insulating film 160 may be selectively disposed between the first and second lower conductive patterns 111 and 112 and between the first and third lower conductive patterns 111 and 113, on the first insulating film 150. The interlayer insulating film 160 may not be formed on the upper surface 111a of each of the first to third lower conductive patterns 111, 112, and 113. That is, the interlayer insulating film 160 may be formed in regions of the first insulating film 150 where the lower metal layer 110 (the first to third conductive patterns 111, 112, 113) is not formed.

An upper surface 160a of the interlayer insulating film 160 may have a convex shape in a third direction Z. In detail, the upper surface 160a of the interlayer insulating film 160 may be formed to be convex in the third direction Z, which is an opposite direction to a direction in which the lower insulating film 100 is positioned.

A lower surface 160b of the interlayer insulating film 160 may be formed to have the same height as the upper surface 150a of the first insulating film 150. For example, in some embodiments, a thickness D1 of the interlayer insulating film 160 may be ten (10) nm or less. However, the technical spirit of the present disclosure is not limited thereto.

The interlayer insulating film 160 may include a metal oxide. For example, the interlayer insulating film 160 may include at least one of aluminum oxide (AlOx), zirconium oxide (ZrOx), and hafnium oxide (HfOx). However, the technical spirit of the present disclosure is not limited thereto.

A capping film 140 may be on the upper surface 111a of each of the first to third lower conductive patterns 111, 112, and 113. The capping film 140 may extend in the first direction X along the upper surface 111a of each of the first to third lower conductive patterns 111, 112, and 113.

As illustrated in FIGS. 2 and 4, the capping film 140 may not be formed on a portion of the upper surface 111a of the first lower conductive pattern 111 where the via metal layer 120 is formed. That is, the capping film 140 may not be formed between the first lower conductive pattern 111 and the via metal layer 120.

However, the technical spirit of the present disclosure is not limited thereto. That is, in some other example embodiments, the capping film 140 may also be formed between the first lower conductive pattern 111 and the via metal layer 120.

The capping film 140 may include, for example, at least one of cobalt (Co), tungsten (W), aluminum (Al), tantalum (Ta), titanium (Ti), nickel (Ni), ruthenium (Ru), or aluminum nitride (AlN).

The barrier dielectric film 180 may be on the first to third lower conductive patterns 111, 112, and 113, the interlayer insulating film 160, and the capping film 140. In this case, the barrier dielectric film 180 may be formed along a profile of the interlayer insulating film 160. In addition, the barrier dielectric film 180 may conform to the interlayer insulating film 160, and in some embodiments may have a uniform thickness, but the technical spirit of the present disclosure is not limited thereto.

The barrier dielectric film 180 may not be formed on a portion of the upper surface 111a of the first lower conductive pattern 111 where the via metal layer 120 is formed. That is, the barrier dielectric film 180 may not be formed between the first lower conductive pattern 111 and the via metal layer 120.

The barrier dielectric film 180 may surround at least a portion of the via metal layer 120. A recess R may be formed on the first lower conductive pattern 111. Specifically, the recess R may be formed to penetrate through the second insulating film 170 to expose the upper surface 111a of the first lower conductive pattern 111. Specifically, the barrier dielectric film 180 may be exposed to a sidewall R1_S defining a first recess portion R1 at the lowermost portion in a recess R, and may surround at least a portion of the via metal layer 120 on the sidewall R1_S defining the first recess portion R1.

The barrier dielectric film 180 may include, for example, aluminum nitride (AlN) or silicon oxycarbide (SiOC). However, the technical spirit of the present disclosure is not limited thereto.

As illustrated in FIG. 3, an anti-oxidation film 181 may be disposed on the barrier dielectric film 180. The anti-oxidation film 181 may not be formed between the first lower conductive pattern 111 and the via metal layer 120.

The anti-oxidation film 181 may be, for example, a film formed as a silicon oxide film, a silicon nitride film, a carbon doped film, or combinations thereof. However, the technical spirit of the present disclosure is not limited thereto.

The second insulating film 170 may be on the etch stop film 190. Specifically, the second insulating film 170 may be on the etch stop film 190, and may surround at least a portion of a sidewall of the via metal layer 120.

The second insulating film 170 may include a low-k material similar to that of the first insulating film 150 described above.

The second insulating film 170 may include a first insulating film portion 171 formed on the interlayer insulating film 160 and a second insulating film portion 172 formed on the first insulating film portion 171. A thickness T2 of the second insulating film portion 172 may be greater than a thickness T1 of the first insulating film portion 171. For example, in some embodiments, the thickness T2 of the second insulating film portion 172 may be up to about seven (7) times the thickness T1 of the first insulating film portion 171. However, the technical spirit of the present disclosure is not limited thereto.

The first insulating film portion 171 of the second insulating film 170 may be on the barrier dielectric film 180. A pore may not be formed in the first insulating film portion 171, in some embodiments.

Carbon concentrations in the first insulating film portion 171 and the second insulating film portion 172 may be different from each other. Specifically, the carbon concentration in the first insulating film portion 171 may be higher than the carbon concentration in the second insulating film portion 172. For example, a carbon concentration in the interlayer insulating film 160 may be measured using a measuring device such as an X-ray photoelectron spectroscopy (XPS). However, the technical spirit of the present disclosure is not limited thereto.

For example, the carbon concentration in the first insulating film portion 171 may be about 20 to about 30 at %, and the carbon concentration in the second insulating film portion 172 may be about 10 to about 20 at %. However, the technical spirit of the present disclosure is not limited thereto.

As discussed above, the recess R may be formed on the first lower conductive pattern 111. Specifically, the recess R may be formed to penetrate through the second insulating film 170 to expose the upper surface 111a of the first lower conductive pattern 111. At least a portion of the barrier dielectric film 180 and at least a portion of the interlayer insulating film 160 may be formed to be recessed toward an inner side of the recess R.

A sidewall defining the recess R may have an inclined profile of which a width in the second direction Y increases as it becomes distant from a top surface of the lower insulating film 100. However, the technical spirit of the present disclosure is not limited thereto.

The recess R may have the first recess portion R1 formed along the profile of the interlayer insulating film 160, a second recess portion R2 penetrating through the first insulating film portion 171 of the second insulating film 170 and extending to the first recess R1, and a third recess portion R3 penetrating through the second insulating film portion 172 of the second insulating film 170 and extending to the second recess portion R2.

Specifically, the first recess portion R1 may be formed along a profile of a concave portion CN between the first and second interlayer insulating films 161 and 162. For example, sidewalls R2_S and R3_S of the second and third recess portions R2 and R3 may have a straight inclined profile, and the sidewall R1_S of the first recess portion R1 may have a curved inclined profile.

However, the technical spirit of the present disclosure is not limited thereto. That is, in some other example embodiments, inclined profiles of an upper sidewall and a lower sidewall defining the recess R may be formed to be the same as each other.

The sidewall R1_S of the first recess portion R1 may have a curved inclined profile by a portion of the barrier dielectric film 180 and a portion of the interlayer insulating film 160 that are recessed toward the inner side of the recess R.

The via metal layer 120 may be inside the recess R. The via metal layer 120 may be electrically connected to the first lower conductive pattern 111.

The via metal layer 120 may include, for example, at least one of aluminum (Al), copper (Cu), tungsten (W), and cobalt (Co).

Referring to FIG. 2, a width W2 of a lower surface 120a of the via metal layer 120 in the second direction Y may be smaller than the width W1 of the upper surface 111a of the first lower conductive pattern 111 in the second direction Y. However, the technical spirit of the present disclosure is not limited thereto.

A width W3 of an upper surface of the via metal layer 120 in the second direction Y may be greater than the width W1 of the upper surface 111a of the first lower conductive pattern 111 in the second direction Y and the width W2 of the lower surface 120a of the via metal layer 120 in the second direction Y. However, the technical spirit of the present disclosure is not limited thereto.

The via metal layer 120 may include a lower via metal layer in contact with the first insulating film portion 171 of the second insulating film 170 and an upper via metal layer formed on the lower via metal layer and in contact with the second insulating film portion 172 of the second insulating film 170. Carbon concentrations in the second insulating film 170 surrounding the upper via metal layer and the lower via metal layer may be different from each other.

A first upper conductive pattern 131 may be on the second insulating film 170 and the via metal layer 120 so as to extend in the second direction Y. The first upper conductive pattern 131 may be electrically connected to the first lower conductive pattern 111 through the via metal layer 120.

A second upper conductive pattern 132 may be on the second insulating film 170 so as to be spaced apart from the first upper conductive pattern 131 in the first direction X and extend in the second direction Y.

It has been illustrated in the drawings that only the first upper conductive pattern 131 is connected to the first lower conductive pattern 111 through the via metal layer 120, but this is for convenience of explanation, and the second upper conductive pattern 132 may also be electrically connected to another lower metal layer.

Referring back to FIG. 2, an upper barrier film 102 may be disposed along a bottom surface and the sidewalls R1_S, R2_S, and R3_S that define the recess R. In addition, the upper barrier film 102 may be between the first and second upper metal layers 131 and the second insulating film 170.

In the semiconductor device according to some example embodiments of the present disclosure, reliability of an electrical connection between the via metal layer 120 and the lower metal layer 110 may be improved by selectively growing the interlayer insulating film 160 only on the first insulating film 150 to prevent the interlayer insulating film 160 from being formed on the lower metal layers 111, 112, and 113. That is, the interlayer insulating film 160 may be formed in regions of the first insulating film 150 where the lower metal layer 110 (the first, second and third lower conductive patterns 111, 112, 113) is not formed.

In the semiconductor device according to some example embodiments of the present disclosure, reliability of the semiconductor device may be improved by forming the interlayer insulating film 160 and the barrier dielectric film 180 so as to be convex in the opposite direction to the direction in which the lower insulating film 100 is positioned to decrease the occurrence of a short-circuit between the lower metal layers 112 and 113 other than the lower metal layer 111 electrically connected to the via metal layer 120 and the via metal layer 120.

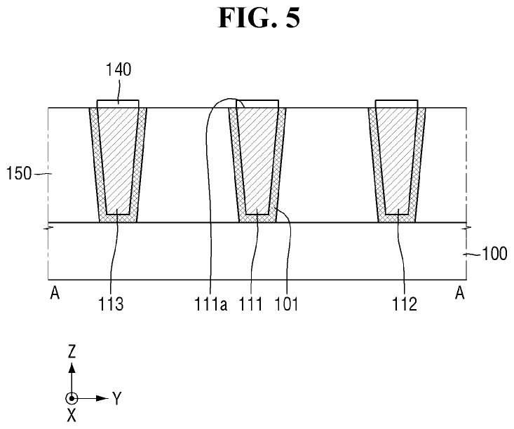

Hereinafter, a method of manufacturing a semiconductor device according to some example embodiments of the present disclosure will be described with reference to FIGS. 5 to 9.

FIGS. 5 to 9 are views for describing a method of manufacturing an example semiconductor device according to some example embodiments of the present disclosure.

Referring to FIG. 5, the first insulating film 150 is formed on the lower insulating film 100. A plurality of recesses may be formed to penetrate through the first insulating film 150. The respective recesses may be formed to extend in the first direction X and be spaced apart from each other in the second direction Y.

The lower barrier films 101 may be formed along bottom surfaces and sidewalls of the respective recesses. The first to third lower conductive patterns 111, 112, and 113 may be formed to at least partially fill the respective recesses.

The capping film 140 may be formed on the upper surface 111a of each of the first to third lower conductive patterns 111, 112, and 113. In this case, the capping film 140 may be selectively formed on the upper surface 111a of each of the first to third lower conductive patterns 111, 112, and 113. However, the technical spirit of the present disclosure is not limited thereto.

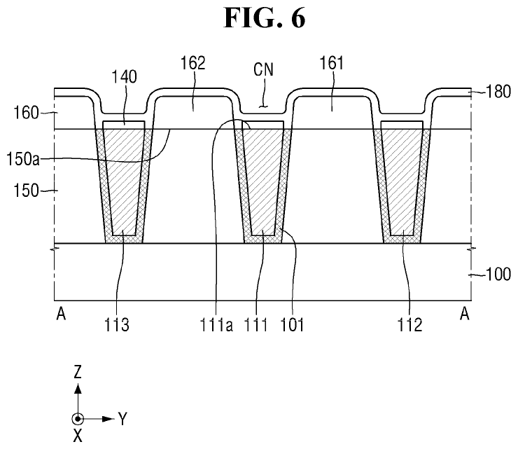

Referring to FIG. 6, the interlayer insulating film 160 may be formed on the upper surface 150a of the first insulating film 150.

The interlayer insulating film 160 may be selectively grown and formed only on the first insulating film 150.

The interlayer insulating film 160 may not be formed on the upper surface 111a of each of the first to third lower conductive patterns 111, 112, and 113. That is, the interlayer insulating film 160 may be formed so as not to overlap each of the first to third lower conductive patterns 111, 112, and 113.

The interlayer insulating film 160 may be formed to be convex in the opposite direction to the direction in which the lower insulating film 100 is positioned. In addition, the concave portion CN corresponding to each of the first to third lower conductive patterns 111, 112, and 113 may be formed between the first and second interlayer insulating films 161 and 162 adjacent to each other.

The barrier dielectric film 180 may be formed on an upper surface of the lower barrier film 101, the capping film 140, and the interlayer insulating film 160. In this case, the barrier dielectric film 180 may conform to an upper surface of each of the lower barrier film 101, the capping film 140, and the interlayer insulating film 160, and in some embodiments, may have a uniform thickness, but the technical spirit of the present disclosure is not limited thereto.

As illustrated in FIG. 3, but not shown in FIG. 6, in some embodiments, the anti-oxidation film 181 may be formed on the barrier dielectric film 180.

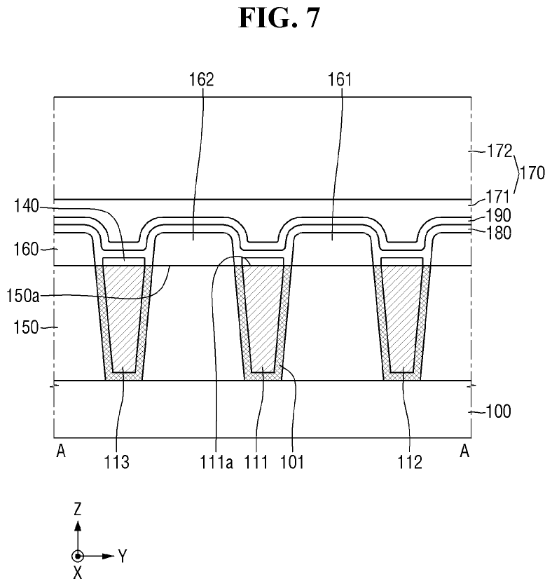

Referring to FIG. 7, the etch stop film 190 may be formed on the barrier dielectric film 180. In this case, the etch stop film 190 may conform to the barrier dielectric film 180, and in some embodiments may have a uniform thickness, but the technical spirit of the present disclosure is not limited thereto. For example, the etch stop film 190 may include a material having an etch selectivity in a relationship with the second insulating film 170.

Subsequently, the second insulating film 170 may be formed on the etch stop film 190. Specifically, the first insulating film portion 171 may be formed on etch stop film 190, and the second insulating film portion 172 may be then formed on the first insulating film portion 171.

For example, the first insulating film portion 171 and the second insulating film portion 172 may be formed by a radical reaction using a carbon precursor and an oxygen gas (O₂) as reactants. The radical reaction may be performed by a plasma device using radio frequency (RF) power.

According to some example embodiments, the carbon precursor may include a silicon-methyl (Si—CH₃) bond. For example, the carbon precursor may be octa-methyl-cyclotetrasiloxane (OMCTs). However, the technical spirit of the present disclosure is not limited thereto.

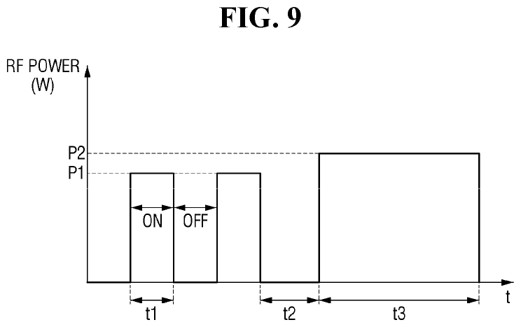

Referring to FIGS. 7 and 9 together, the first insulating film portion 171 may be formed using pulsed RF plasma, and the second insulating film portion 172 may be formed using continuous wave (CW) RF plasma. Specifically, in a process of forming the first insulating film portion 171, RF power when the RF power is in an on-state may be a first RF power P1. RF power for forming the second insulating film portion 172 may be a second RF power P2.

In the process of forming the first insulating film portion 171, the first RF power P1 is maintained for a predetermined time t1.

When the RF power is in an off-state, a density and/or a mobility of electrons and cations decreases, such that deposition of the first insulating film portion 171 may advantageously occur. In this case, the first insulating film portion 171 is at least partially filled in the concave portion CN between the first and second interlayer insulating films 161 and 162, and thus, a pore that may be formed in the first insulating film portion 171 may be reduced or eliminated. Meanwhile, formation conditions of pulsed plasma, such as a pressure, a gas amount, and a frequency, may be changed according to a thickness of the first insulating film portion 171 to be filled.

After the first insulating film portion 171 is deposited and before the second insulating film portion 172 is deposited, the RF power may be maintained in an off-state for a predetermined time t2 in order to stabilize a process environment.

Thereafter, a magnitude of the RF power, a ratio between the reactants, and/or a flow rate when the second insulating film portion 172 is formed may be different from those when the first insulating film portion 171 is formed. Accordingly, the second insulating film portion 172 having a film quality different from that of the first insulating film portion 171 may be formed.

For example, the second RF power P2 stronger than the first RF power P1 may be applied for a time t3 longer than that when the first insulating film portion 171 is formed. In this case, the second insulating film portion 172 having a film quality harder than that of the first insulating film portion 171 may be formed. As a result, in a process of patterning the second insulating film portion 172 in order to form the via metal layer 120, a wiggling phenomenon (undulation) of the second insulating film portion 172 may be minimized or reduced.

In a series of processes of forming the first insulating film portion 171 and the second insulating film portion 172 as described above, the carbon concentration in the second insulating film portion 172 may be different from the carbon concentration in the first insulating film portion 171. The carbon concentration in the first insulating film portion 171 may be higher than the carbon concentration in the second insulating film portion 172. For example, in some embodiments, the carbon concentration in the first insulating film portion 171 may be about 20 to about 30 at %, and the carbon concentration in the second insulating film portion 172 may be about 10 to 20 at %. In addition, in a series of processes of forming the first insulating film portion 171 and the second insulating film portion 172 as described above, the thickness T2 of the second insulating film portion 172 may be greater than the thickness T1 of the first insulating film portion 171.

That is, when the first insulating film portion 171 is formed, the first insulating film portion 171 may be formed to have a film quality that may be easily filled in the concave portion CN by controlling the density and/or the mobility of the electrons and the cations using the pulsed plasma.

When the second insulating film portion 172 is formed, the second insulating film portion 172 having a film quality harder than that of the first insulating film portion 171 may be formed by using the continuous wave (CW) RF plasma.

Meanwhile, the processes of forming the first insulating film portion 171 and the second insulating film portion 172 may be performed in-situ. As a result, the first insulating film portion 171 and the second insulating film portion 172 having different film qualities may be formed in the same reaction space, such that the number of processes may be further simplified.

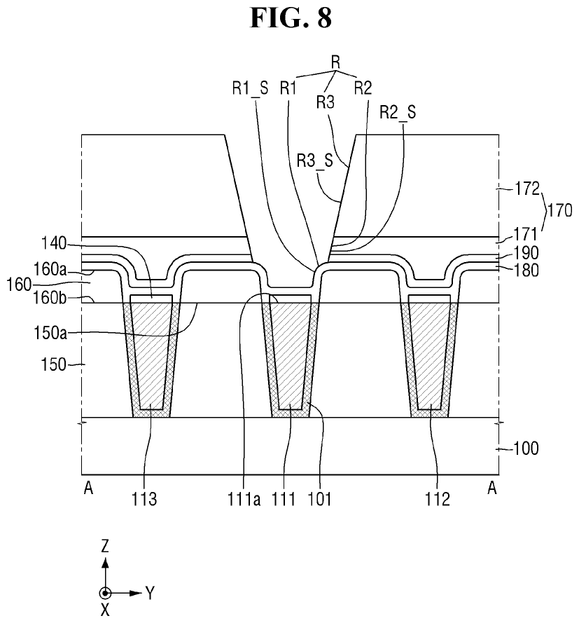

Referring to FIG. 8, the recess R penetrating through the second insulating film 170 may be formed by etching the second insulating film 170. In this case, the etch stop film 190, the barrier dielectric film 180, and the capping film 140 formed on the first lower conductive pattern 111 are sequentially etched, such that the upper surface 111a of the first lower conductive pattern 111 may be exposed.

In addition, portions of side surfaces of the etch stop film 190 and a portion of the barrier dielectric film 180 may be exposed to the recess R.

It has illustrated in FIG. 8 that the barrier dielectric film 180 exposed to the sidewall defining the recess R is not etched, but the barrier dielectric film 180 exposed to the sidewall defining the recess R may be partially etched in a process of forming the recess R.

In addition, it has been illustrated in FIG. 8 that the capping film 140 formed on the first lower conductive pattern 111 is etched in the process of forming the recess R, but the technical spirit of the present disclosure is not limited thereto. That is, in some other example embodiments, the capping film 140 may also not be etched in the process of forming the recess R.

Next, referring to FIG. 2, the upper barrier film 102 may be formed on the bottom surface of the recess R (opposite the top surface of the capping film 140) and along the sidewalls of the second insulating film 170 defining the recess R, which form the sidewalls R1_S, R2_S, and R3_S. The upper barrier film 102 may also be formed on an upper surface of the second insulating film 170. The upper barrier film 102 may conform to the upper surface of the second insulating film 170, and in some embodiments, may have a uniform thickness, but the technical spirit of the present disclosure is not limited thereto.

The via metal layer 120 may be formed on the upper barrier film 102 so as to at least partially fill the recess R. In addition, the first upper conductive pattern 131 may be formed on the upper barrier film 102, which is formed on the upper surface of the second insulating film 170 and on the via metal layer 120.

The via metal layer 120 and the first upper conductive pattern 131 may be formed by the same process. However, the technical spirit of the present disclosure is not limited thereto. That is, in some other example embodiments, the via metal layer 120 and the first upper conductive pattern 131 may also be formed by different processes.

The semiconductor device illustrated in FIG. 2 may be manufactured through the method of manufacturing a semiconductor device described above.

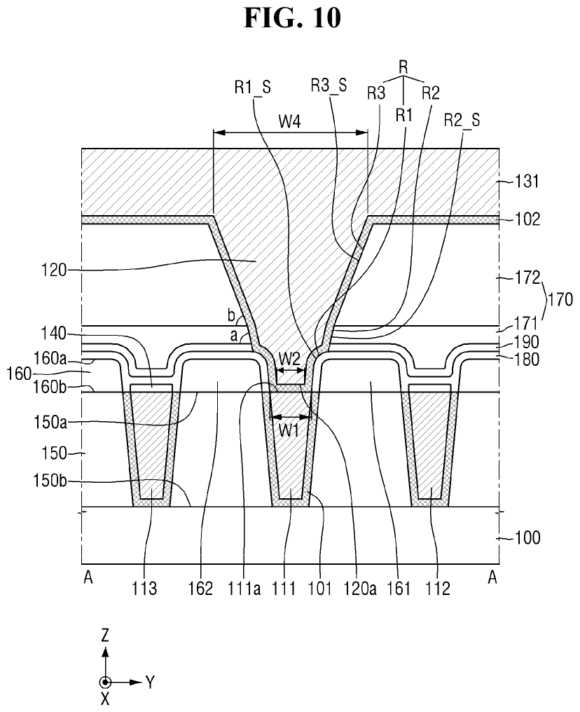

Hereinafter, a semiconductor device according to some other example embodiments of the present disclosure will be described with reference to FIG. 10. Contents different from those of the semiconductor device illustrated in FIG. 2 will be mainly described.

FIG. 10 is a view for describing a semiconductor device according to some example embodiments of the present disclosure, and is a view corresponding to the cross-sectional view taken along line A-A of FIG. 1.

Referring to FIG. 10, inclined profiles of the sidewalls R2_S and R3_S of the second and third recess portions R2 and R3 of a semiconductor device according to some example embodiments of the present disclosure may be different from each other. For example, a gradient a of the sidewall R2_S with respect to a surface parallel to the upper surface of the first insulating film 150 may be greater than a gradient b of the sidewall R3_S with respect to a surface parallel to the upper surface of the first insulating film 150. However, the technical spirit of the present disclosure is not limited thereto.

A width W4 of an upper surface of a via metal layer 120 in the second direction Y may be greater than the width W3 of the upper surface of the via metal layer 120 in the second direction Y, illustrated in FIG. 2. An extension line of the inclined profile of the sidewall R3_S may not coincide with an extension line of an inclined profile of the sidewall of the first lower conductive pattern 111.

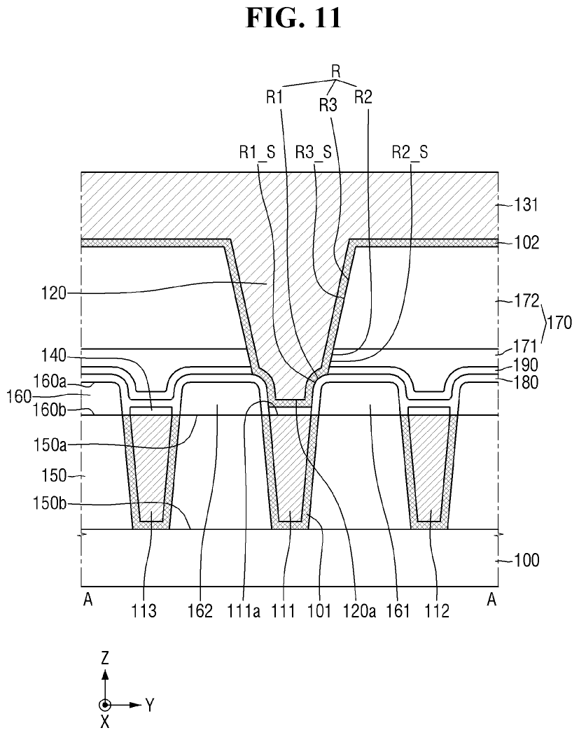

Hereinafter, a semiconductor device according to some other example embodiments of the present disclosure will be described with reference to FIG. 11. Contents different from those of the semiconductor device illustrated in FIG. 2 will be mainly described.

FIG. 11 is a view for describing a semiconductor device according to some example embodiments of the present disclosure, and is a view corresponding to the cross-sectional view taken along line A-A of FIG. 1.

Referring to FIG. 11, in a semiconductor device according to some other example embodiment of the present disclosure, the capping film 140 may be between the upper surface 111a of the first lower conductive pattern 111 and the lower surface 120a of the via metal layer 220. That is, the capping film 140 may be exposed by the bottom surface of the recess R.

The upper barrier film 102 may be disposed along the bottom surface of the recess R (opposite the top surface of the capping film 140) and along the sidewalls R1_S, R2_S, and R3_S, and along the upper surface of the second insulating film 170. The via metal layer 120 may be on the upper barrier film 102 so as to at least partially fill the recess R. In addition, the first upper conductive pattern 131 may be formed on the upper barrier film 102, which is formed on the upper surface of the second insulating film 170 and the via metal layer 120.

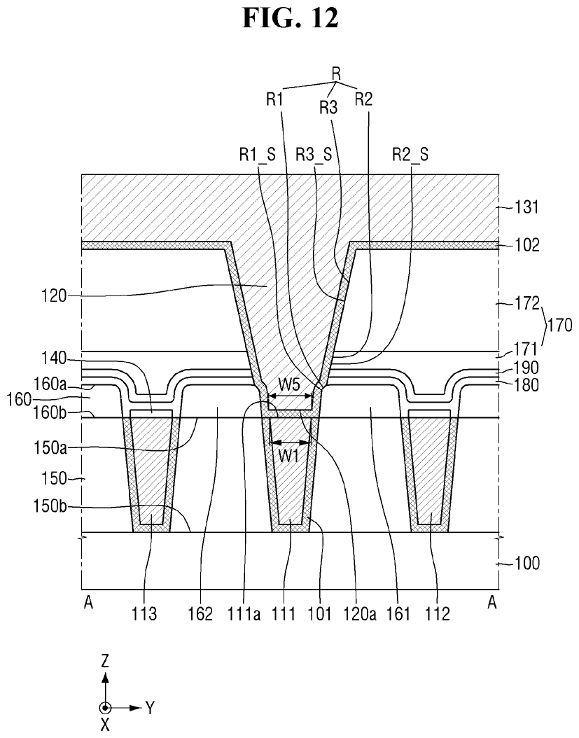

Hereinafter, a semiconductor device according to some other example embodiments of the present disclosure will be described with reference to FIG. 12. Contents different from those of the semiconductor device illustrated in FIG. 2 will be mainly described.

FIG. 12 is a view for describing a semiconductor device according to some example embodiments of the present disclosure, and is a view corresponding to the cross-sectional view taken along line A-A of FIG. 1.

Referring to FIG. 12, in a semiconductor device according to some other example embodiments of the present disclosure, the barrier dielectric film 180 is etched in the process of forming the recess R, such that the upper barrier film 102 may be in direct contact with the interlayer insulating film 160.

A portion of the interlayer insulating film 160 may be recessed toward an inner side of the recess R. Side surfaces of the interlayer insulating film 160 and the barrier dielectric film 180 may be exposed to the sidewalls R1_S and R2_S.

The width W1 of the upper surface 111a of the first lower conductive pattern 111 in the second direction Y may be the same as a width W5 of the lower surface 120a of the via metal layer 120 in the second direction Y. However, the technical spirit of the present disclosure is not limited thereto.

The first upper conductive pattern 131 may be formed on the upper barrier film 102, which is formed on the upper surface of the second insulating film 170 and the via metal layer 120.

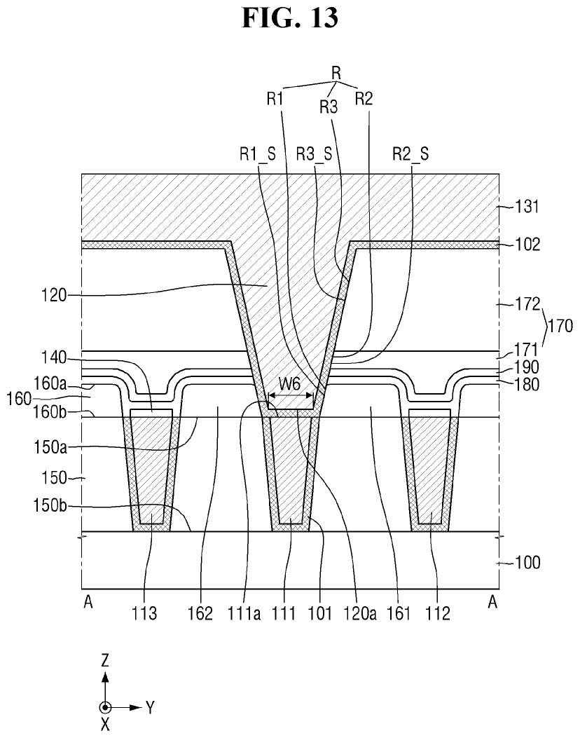

Hereinafter, a semiconductor device according to some other example embodiments of the present disclosure will be described with reference to FIG. 13. Contents different from those of the semiconductor device illustrated in FIG. 2 will be mainly described.

FIG. 13 is a view for describing a semiconductor device according to some example embodiments of the present disclosure, and is a view corresponding to the cross-sectional view taken along line A-A of FIG. 1.

Referring to FIG. 13, in a semiconductor device according to some other example embodiments of the present disclosure, portions of the barrier dielectric film 180 and the interlayer insulating film 160 may be etched in the process of forming the recess R. Therefore, the sidewalls R1_S, R2_S, and R3_S may have the same inclined profile.

The upper barrier film 102 may be along the bottom surface of the recess R (opposite the top surface of the capping film 140) and along the sidewalls R1_S, R2_S, and R3_S, and along the upper surface of the second insulating film 170. The via metal layer 120 may be on the upper barrier film 102 so as to at least partially fill the recess R. In addition, the first upper conductive pattern 131 may be formed on the upper barrier film 102, which is formed on the upper surface of the second insulating film 170 and the via metal layer 120.

A lower surface 120a of the via metal layer 120 may be formed to have a width W6 that is greater than that of the width W2 of the lower surface 120a of the via metal layer 120 in the second direction Y illustrated in FIG. 2.

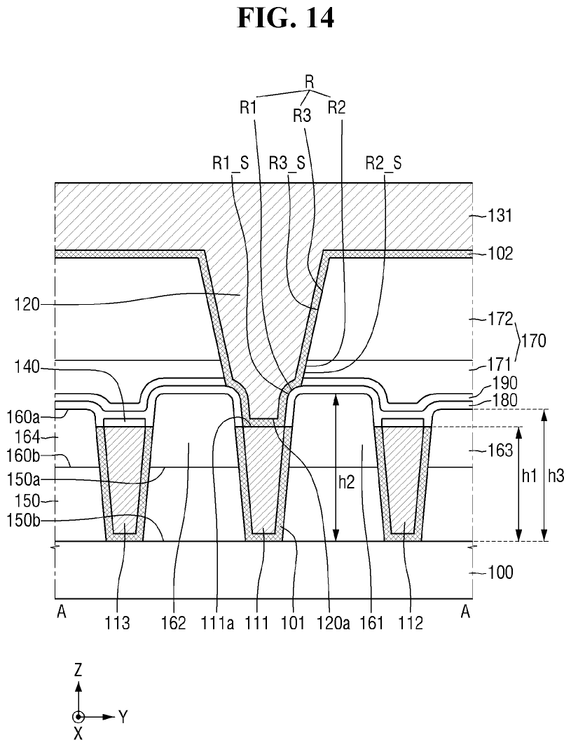

Hereinafter, a semiconductor device according to some other example embodiments of the present disclosure will be described with reference to FIG. 14. Contents different from those of the semiconductor device illustrated in FIG. 2 will be mainly described.

FIG. 14 is a view for describing a semiconductor device according to some example embodiments of the present disclosure, and is a view corresponding to the cross-sectional view taken along line A-A of FIG. 1.

Referring to FIG. 14, the interlayer insulating film 160 may include first interlayer insulating film 161 and second interlayer insulating film 162 in first and second regions of the interlayer insulating film 160 adjacent to the via metal layer 120 and third interlayer insulating film 163 and fourth interlayer insulating film 164 in third and fourth regions other than the first and second regions where the first interlayer insulating film 161 and the second interlayer insulating film 162 are disposed.

The upper surface 111a of each of the first to third lower conductive patterns 111, 112, and 113 may be formed closer to the lower insulating film 100 than the upper surface 160a of the interlayer insulating film 160 is.

Specifically, a height h2 from the lower insulating film 100 to upper surfaces of the first and second interlayer insulating films 161 and 162 of the interlayer insulating film 160 may be greater than a height h1 from the lower insulating film 100 to the upper surface 111a of each of the first to third lower conductive patterns 111, 112, and 113. A height h3 from the lower insulating film 100 to upper surfaces of the third and fourth interlayer insulating films 163 and 164 of the interlayer insulating film 160 may be greater than the height hl from the lower insulating film 100 to the upper surface 111a of each of the first to third lower conductive patterns 111, 112, and 113.

In this case, the interlayer insulating film 160 may be formed to surround at least portions of side surfaces of each of the first to third lower conductive patterns 111, 112, and 113.

Although not specifically illustrated, portions of an upper portion of the first insulating film 150 of FIG. 5 may be etched. Therefore, an upper surface of the first insulating film 150 may be formed closer to the lower insulating film 100 than the upper surfaces 111a of each of the first to third lower conductive patterns 111, 112, and 113 is.

The upper surfaces of the third and fourth interlayer insulating films 163 and 164 of the interlayer insulating film 160 may be formed closer to the lower insulating film 100 than the upper surfaces of the first and second interlayer insulating films 161 and 162 of the interlayer insulating film 160 are.

Specifically, the height h2 from the lower insulating film 100 to the upper surfaces of the first and second interlayer insulating films 161 and 162 of the interlayer insulating film 160 may be greater than the height h3 from the lower insulating film 100 to the upper surfaces of the third and fourth interlayer insulating films 163 and 164 of the interlayer insulating film 160.

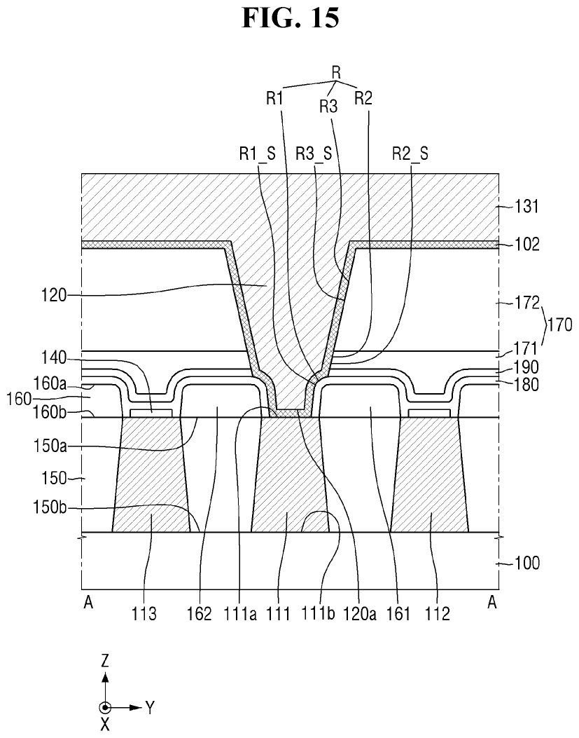

Hereinafter, a semiconductor device according to some other example embodiments of the present disclosure will be described with reference to FIGS. 15 to 19. Contents different from those of the semiconductor devices illustrated in FIGS. 2 and 10 to 14 will be mainly described. The semiconductor devices in FIGS. 15-19 are similar to the semiconductor devices in FIGS. 2 and 10-14, respectively, but with various differences including, but not limited to, a difference in the shape and/or profile of the first to third lower conductive patterns 111, 112, and 113 as formed.

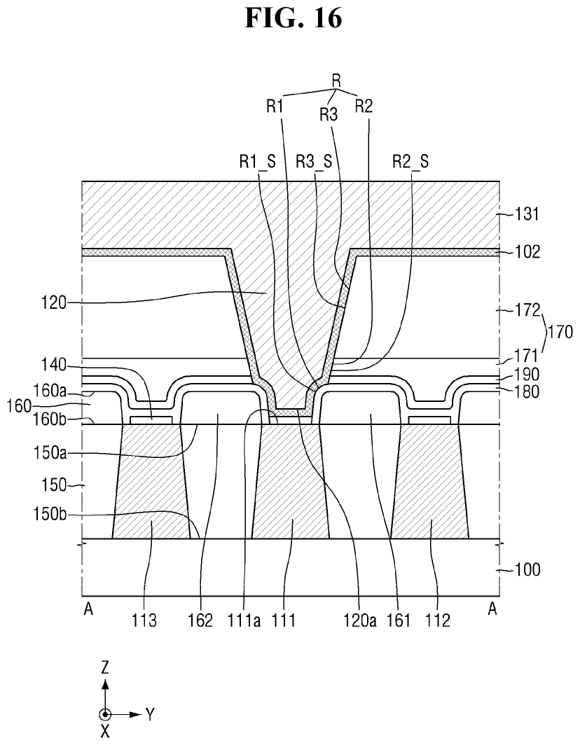

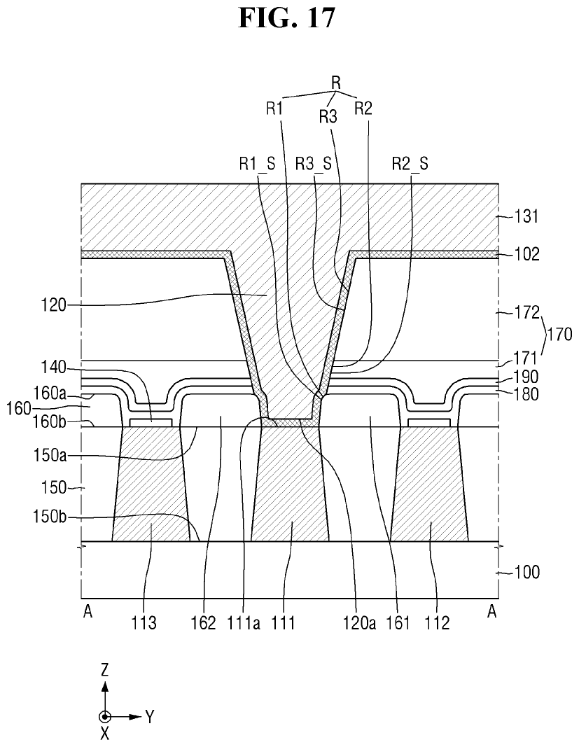

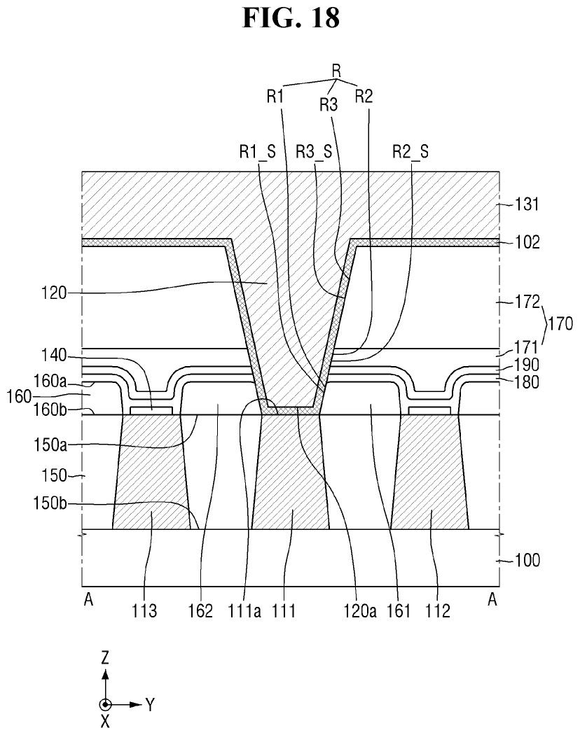

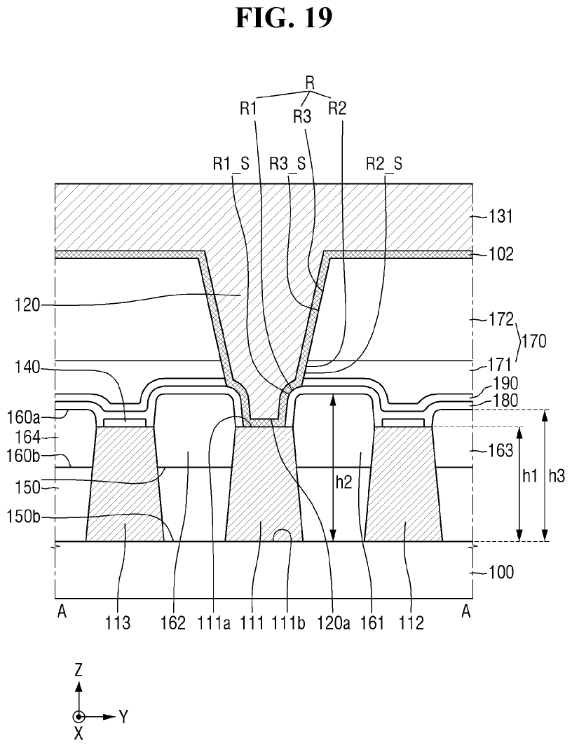

FIG. 15 is a view for describing an example semiconductor device according to some example embodiments of the present disclosure, and is a view corresponding to the cross-sectional view taken along line A-A of FIG. 1. FIG. 16 is a view for describing an example semiconductor device according to some example embodiments of the present disclosure, and is a view corresponding to the cross-sectional view taken along line A-A of FIG. 1. FIG. 17 is a view for describing an example semiconductor device according to some example embodiments of the present disclosure, and is a view corresponding to the cross-sectional view taken along line A-A of FIG. 1. FIG. 18 is a view for describing an example semiconductor device according to some example embodiments of the present disclosure, and is a view corresponding to the cross-sectional view taken along line A-A of FIG. 1. FIG. 19 is a view for describing an example semiconductor device according to some example embodiments of the present disclosure, and is a view corresponding to the cross-sectional view taken along line A-A of FIG. 1.

Referring to FIGS. 15 to 19, the first, second, and third lower conductive patterns 111, 112, and 113 of the semiconductor device according to some example embodiments of the present disclosure may be formed by a method of etching the lower metal layer 110.

In this case, the lower metal layer 110 may be formed by forming a metal other than copper (Cu) on the lower insulating film 100. Each of the first to third lower conductive patterns 111, 112, and 113 may include, for example, at least one of silver (Ag), tungsten (W), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), molybdenum (Mo), ruthenium (Ru), or zirconium (Zr). However, the technical spirit of the present disclosure is not limited thereto.

Specifically, although not illustrated, a recess is formed by etching the lower metal layer 110 on the lower insulating film 100. Thereafter, the first insulating film 150 is formed in the recess. Accordingly, a width in the Y direction of an upper surface of each of the first, second, and third conductive patterns 111, 112, and 113 of the lower metal layer 110 may be smaller than a width of a lower surface thereof.

Example embodiments according the technical spirit of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A semiconductor device comprising:
a lower metal layer comprising first, second, and third conductive patterns spaced apart from each other in a first insulating film;
a first interlayer insulating film between the first and second conductive patterns;
a second interlayer insulating film between the second and third conductive patterns, wherein the first and second interlayer insulating films are spaced apart from each other on the first insulating film;
a via metal layer inside a recess on the lower metal layer, the via metal layer electrically connected to the lower metal layer; and
a second insulating film at least partially surrounding side surfaces of the via metal layer, the second insulating film comprising:
a first insulating film portion formed on a concave portion between the first interlayer insulating film and the second interlayer insulating film; and
a second insulating film portion on the first insulating film portion, and
wherein a carbon concentration in the first insulating film portion is higher than a carbon concentration in the second insulating film portion.

2. The semiconductor device of claim 1, wherein the recess comprises a first recess portion formed along the first interlayer insulating film and the second interlayer insulating film, a second recess portion penetrating through the first insulating film portion and extending to the first recess portion, and a third recess portion penetrating through the second insulating film portion and extending to the second recess portion.

3. The semiconductor device of claim 2, wherein profiles of sidewalls of the first and second recess portions are different from each other, with a sidewall of the first recess portion having a curved inclined profile and a sidewall of the second recess portion having a straight inclined profile.

4. The semiconductor device of claim 2, wherein profiles of sidewalls of the second and third recess portions are different from each other.

5. The semiconductor device of claim 1, wherein a thickness of the second insulating film portion is greater than a thickness of the first insulating film portion.

6. The semiconductor device of claim 1, further comprising a barrier dielectric film on the first interlayer insulating film and on the second interlayer insulating film,
wherein the first insulating film portion is on the barrier dielectric film.

7. The semiconductor device of claim 6, further comprising an etch stop film between the barrier dielectric film and the first insulating film portion.

8. The semiconductor device of claim 6, wherein
the barrier dielectric film surrounds at least a portion of the via metal layer, and
at least a portion of the barrier dielectric film is recessed toward an inner side of the recess.

9. The semiconductor device of claim 1, wherein at least a portion of the first interlayer insulating film and at least a portion of the second interlayer insulating film are recessed toward an inner side of the recess.

10. The semiconductor device of claim 1, wherein the first interlayer insulating film and the second interlayer insulating film are formed to be convex in an opposite direction to a direction in which the first insulating film is positioned.

11. The semiconductor device of claim 1, wherein a pore is not formed in the first insulating film portion.

12. The semiconductor device of claim 1, wherein
the carbon concentration in the first insulating film portion is between about 20 at % and about 30 at %, and
the carbon concentration in the second insulating film portion is between about 10 at % and about 20 at %.

13. A semiconductor device comprising:
a lower metal layer in a first insulating film;
an interlayer insulating film selectively formed on the first insulating film in one or more regions where the lower metal layer is not formed;
a via metal layer on the lower metal layer and electrically connected to the lower metal layer; and
a second insulating film at least partially surrounding side surfaces of the via metal layer and comprising a first insulating film portion on the interlayer insulating film having a first carbon concentration and a second insulating film portion on the first insulating film portion having a second carbon concentration lower than the first carbon concentration.

14. The semiconductor device of claim 13, wherein the via metal layer is inside a recess on the lower metal layer,
wherein the recess comprises a first recess portion formed along the interlayer insulating film, a second recess portion penetrating through the first insulating film portion and extending to the first recess portion, and a third recess portion penetrating through the second insulating film portion and extending to the second recess portion, and
wherein profiles of sidewalls of the first and second recess portions are different from each other.

15. The semiconductor device of claim 14, wherein profiles of sidewalls of the second and third recess portions are different from each other.

16. The semiconductor device of claim 13, further comprising:
a barrier dielectric film on the interlayer insulating film; and
an etch stop film on the barrier dielectric film,
wherein the first insulating film portion of the second insulating film is on the etch stop film.

17. The semiconductor device of claim 13, wherein a thickness of the second insulating film portion is greater than a thickness of the first insulating film portion.

18. A semiconductor device comprising:
a lower metal layer comprising first, second, and third conductive patterns spaced apart from each other in a first insulating film, wherein a width of an upper surface of each of the first, second, and third conductive patterns of the lower metal layer is less than a width of a lower surface of the respective first, second, and third conductive patterns;
a first interlayer insulating film between the first and second conductive patterns;
a second interlayer insulating film between the second and third conductive patterns, wherein the first and second interlayer insulating films are spaced apart from each other on the first insulating film;
a via metal layer inside a recess on the lower metal layer, the via metal layer electrically connected to the lower metal layer; and
a second insulating film at least partially surrounding side surfaces of the via metal layer and comprising a first insulating film portion on a concave portion between the first and second interlayer insulating films and a second insulating film portion on the first insulating film portion,
wherein the recess comprises a first recess portion formed along a concave portion between the first and second interlayer insulating films, a second recess portion penetrating through the first insulating film portion and extending to the first recess portion, and a third recess portion penetrating through the second portion and extending to the second recess portion, and
wherein a carbon concentration in the first insulating film portion is higher than a carbon concentration in the second insulating film portion.

19. The semiconductor device of claim 18, wherein profiles of sidewalls of the second and third recess portions are different from each other, with a gradient of the sidewall of the second recess portion with respect to a surface parallel to an upper surface of the first insulating film being greater than a gradient of the sidewall of the third recess portion with respect to the surface parallel to the upper surface of the first insulating film.

20. The semiconductor device of claim 18, wherein a thickness of the second insulating film portion is about seven times a thickness of the first insulating film portion.
